(19) United States
(12) Patent Application Publication
(10) Pub. No.: US 2004/0159903 A1
(43) Pub. Date: Aug. 19, 2004

(54) Compounds and solid state apparatus having electroluminescent properties

(76) Inventors: Robert H. Burgener II, Park City, UT (US); Roger L. Felix, Pleasant Grove, UT (US); Gary M. Renlund, Salt Lake City, UT (US)

Correspondence Address: MADSON & METCALF, GATEWAY TOWER WEST, SUITE 900, 15 WEST SOUTH TEMPLE, SALT LAKE CITY, UT, 84101

(21) Appl. No.: 10/780,422

(22) Filed: Feb. 17, 2004

Related U.S. Application Data
(60) Provisional application No. 60/447,511, filed on Feb. 14, 2003.

(51) Int. Cl. H01L 31/0232

(52) U.S. Cl. 257/432

(57) ABSTRACT

Electroluminescent materials and devices which emit non-thermal light in response to an electric field are disclosed. The electroluminescent materials are based upon a multicomponent ceramic oxide host compound and one or more metal oxide dopant compounds which form a solid solution with the ceramic oxide host compound. The dopant is present in the host at an amount in the range from about 0.002 mole % to 0.1 mole %. In the electroluminescent devices, a layer of electroluminescent material is disposed between a transparent conductive oxide layer and a ground plane. An electric field generator is electrically connected to the conductive oxide layer and the ground plane for generating an electric field. The layer of electroluminescent material is coated with at least one barrier layer, and preferably a pair of barrier layers, to inhibit chemical reaction of the electroluminescent material. The electroluminescent devices preferably include a dielectric layer.

### CROSS-REFERENCED RELATED APPLICATIONS

This application claims the benefit of U.S. Provisional Application No. 60/447,511, filed Feb. 14, 2003, which is incorporated by reference.

### BACKGROUND OF THE INVENTION

The present invention provides compounds exhibiting electroluminescent properties when subjected to an electric field and related electroluminescent devices.

Electroluminescent (EL) devices within the scope of the present invention differ from the more familiar light emitting diodes (LED). In LEDs light is generated by electron-hole recombination at a semiconductor p/n junction. The light is typically emitted either through the “p” side of the junction or from the device edge. In contrast, EL devices operate on the principle of impact excitation of a “light emitting center,” usually called a luminescent center or activator. Impact excitation is performed by accelerating electrons in a high electric field, usually >10⁸ V/m. These types of devices are characterized or sub-divided by whether the luminescent centers are processed by thin or thick film technologies and whether they are driven by AC or DC electric fields. The present discussion will focus primarily upon the high field electroluminescent (HFEL) devices.

Table 1, below, compares and contrasts various lighting technologies, including incandescent light, LED devices, Fluorescent light, OLED, and HFEL devices.

TABLE 1

| Incandescent | | Fluorescent | | |
|---|---|---|---|---|
| Light | LED Devices | Light | OLED | HFEL |
| 10% Efficient | Up to 35% | 15% Efficient | Very low efficiency, | Potentially greater |
| | Efficient | | at present | than 90% Efficient |
| Glass/vacuum tube | Plastic | Glass/vacuum tube | No Glass/vacuum | No Glass/vacuum |
| | encapsulation | | tube | tube |
| Fragile | Robust | Fragile | Flexible | Robust |
| Can take heat or | Cannot take heat or | Can take heat or | Cannot take heat or | Can take heat or |
| high power | power | high power | high power | high power |
| 100's of hours | 1000's of hours | 1000's of hours | Short lifetime, at | 1000's of hours |
| lifetime | lifetime | lifetime | present | lifetime |
| Cheap | Expensive now, but | Cheap | Expensive now, but | Cheap |
| | decreasing | | decreasing | |
| Area illumination | Discrete point of | Area illumination | Area illumination | Area illumination |
| | light | | | |
| Variable colors & | Limited color | Limited color | Limited color | Wide range of color |
| brightness | rendering | rendering | rendering | balance |
| Filament | Gradual degradation | Slow degradation | Rapid degradation | Very slow |
| degradation | | | | degradation |

From Table 1, a comparison of properties, implementation of applications, and operational theory shows that HFEL devices have desirable properties and potential for general illumination that have not been developed.

In the field of solid state lighting devices, it will be appreciated that electroluminescent (EL) devices have several advantages over LED devices. A brief comparison of high field electroluminescent devices with light emitting diode devices can be summarized by the following items:

HFEL devices are inherently an area illuminator rather than the point light sources typical of LEDs. Semiconductor processing required for LEDs is sensitive to area yields during fabrication of the p/n junctions. The larger the area of a p/n junction the higher the probability of finding defects so that device yields are not economical. Typical LED areas are about 50 to 200 micrometers on a side. Clustering of hundreds to thousands of individual LEDs is required to provide significant area illumination. In contrast, HFEL devices are not so sensitive to manufacturing defects and indeed are made more efficient as area illuminators, as shown in Equation 1, below.

Most LED devices are single crystal materials made by MOCVD deposition on lattice matched or graded substrates to minimize thermal expansion strains during fabrication and in-use function. The cost of substrates is often the most expensive material component in an LED. Packaging of LEDs to get optimal reflectivity and alignment of the optical and mechanical axis affect manufacturing costs. The degradation of the polymer encapsulants limit expected lifetimes. This is especially true for the blue emitters and for gallium nitride based ultraviolet emitters that use down conversion phosphors to generate white light. There are large discrepancies in published lifetimes for LEDs ranging from 6,000 hours to 80,000 hours. A realistic appraisal of expected lifetimes before degradation reaches about 85% of the initial output, which is the usually agreed upon limit of use, is about 6,000 hours for high brightness LEDs.

The solid state physics associated with HFED devices allow for light to be emitted from HFED devices at a much broader wavelength than the light emitted from LEDs. The design of lighting applications is dependent on the “quality” of the light. When using non-black body radiation for lighting applications, one usually obtains narrower light emissions so CIE (Commission Internationale de L'Eclairage) color coordinates and CCT (Correlated Color Temperatures) are used to generate an appropriate blend of red, green, blue or other design variants such as blue and yellow colors to generate a pleasing white light. The broader individual bands of sub-colors generated by HFED devices permit one to more easily engineer and design a white light emitter for desired lighting applications.

The efficiency of LEDs decrease as the emitted light wavelength decreases from infrared to red to green to blue and now bordering on UV emissions. There are large claims for efficiency in LEDs ranging from 35% to 85%. But, the LED devices have now matured to the extent that realistic constraints can be placed on the technology. The average overall efficiency expected from high brightness LED technology is about 20% to 35%. It is expected that market share for LED lighting applications will increase. In comparison, HFEL devices based on doped zinc sulfides, that are now on the commercially available, have overall efficiencies of >90% conversion of electrical power in to actual light output. However, the available light spectrum and brightness of the ZnS-based HFEL devices is limited to dim non-white light.

Other major issues that confront high brightness LEDs include the following: thermal management is critical for color rendering and long life expectancy; complicated packaging is a large and inherent cost in LED manufacture; white light issues include phosphor degradation, UV bleed-through, and non-uniform color red, green, blue (RGB) LEDs; discrete wavelengths have advantages but also create significant problems in color rendering.

Commercially available electroluminescent devices are based primarily on zinc sulfide doped with manganese and copper, in either the blende or wurtzite structures. A significant disadvantage of zinc sulfide compounds is chemical instability, particularly oxidation of zinc sulfide. These zinc sulfide-based EL materials produce a limited number of colors. The blue color is derived primarily from a cerium activated luminescent center and more recently with other rare-earth activators along alkaline-earth thiogallates. While the melting points for many of these compounds are quite high, sometimes greater than 1,000° C., in an oxidizing atmosphere the sulfides react to form oxides. The instability of the sulfides in general can be easily seen as “bum in” ghost images as the degradation of phosphors occur in cathode-ray tube (CRT) and electroluminescent displays.

When dealing with low chemical stability materials, such as zinc sulfides, a significant fraction of the applied voltage must be used to overcome inherent parasitic losses in the luminescent material. These losses must be overcome through application of large voltage suppressing the minimum threshold voltage of illumination.

Technical challenges to date have limited the application of HFEL devices to small niche markets. But, with a change in materials of construction, HFEL devices show promise for a breakthrough in high efficiency general illumination. It would be an advancement in the art to provide electroluminescent materials having improved chemical stability so that corresponding HFEL devices may produce high power, high brightness, and more efficient lighting.

### BRIEF SUMMARY OF THE INVENTION

The present invention is drawn to electroluminescent materials and devices which emit non-thermal light in response to an electric field. The electroluminescent materials are based upon a multicomponent ceramic oxide host compound and one or more metal oxide dopant compounds which form a solid solution with the ceramic oxide host compound. The ceramic oxide host compound includes at least two metal oxide compounds. A first metal oxide compound is selected from ZrO₂, Ga₂O₃, GeO₂, SnO₂, and PbO₂, and a second metal oxide compound, different from the first metal oxide compound, is selected from ZrO₂, GeO₂, SnO₂, Al₂O₃, Y₂O₃, ZnO, MgO, CaO, Ga₂O₃, SrO, and La₂O₃. The one or more dopant compounds are selected to be different than the ceramic oxide host and include metal oxides selected from MnO₂, SnO₂, HfO₂, Al₂O₃, Dy₂O₃, As₂O₃, and Eu₂O₃, and mixtures thereof. The dopant is preferably present in the host at an amount in the range from about 0.002 mole % to 0.1 mole %. Without being bound by theory, matching the ionic radii of the dopant material with the ionic radii of the host compounds is important to keep the dopant in solid solution with the host.

For example, when the ceramic oxide host compound comprises GeO₂ as the first metal oxide, then the second metal oxide compound may be ZrO₂, Al₂O₃, Y₂O₃, ZnO, MgO, CaO, SrO, and mixtures thereof. When the ceramic oxide host compound comprises ZrO₂ as the first metal oxide, then the second metal oxide may be GeO₂, and Ga₂O₃, SrO, and mixtures thereof. When the ceramic oxide host compound comprises Ga₂O₃ as the first metal oxide, then the second metal oxide may be ZrO₂, SrO, La₂O₃, and mixtures thereof.

The ceramic oxide host compound comprises multiple metal oxides to provide a crystal structure that is compatible with the one or more dopant compounds. Matching ionic radii between the host and dopant materials may help determine compatibility. The metal oxide dopant compounds may provide acceptor and donor sites within the ceramic oxide host compound to facilitate the electroluminescent properties. Electroluminescent devices need electrons that are accelerated in an electric field to an energy of 2 to 3 eV or more. Light emission is obtained when an accelerated electron excites a luminescent center, and photo-emission originates from an electron transition between the excited state and a lower energy level. Electrons within the host material should have the ability to accelerate to the desired threshold energy within the electric field applied. Accordingly, wide band gap host materials are desirable, typically in the range from 3 to 4 eV and greater.

In the electroluminescent devices, a layer of electroluminescent material is located between a transparent conductive oxide layer and a ground plane. An electric field generator is electrically connected to the conductive oxide layer and the ground plane for generating an electric field. The layer of electroluminescent material is coated with at least one barrier layer, and preferably a pair of barrier layers, to inhibit chemical reaction of the electroluminescent material. The barrier layer preferably comprises a low reactive material that is stable at high temperature. The barrier layer is preferably a metal oxide. Examples of possible metal oxide materials that have low reactivity and are stable at high temperatures include, but are not limited to, tantalum oxide (Ta₂O₅), alumina (Al₂O₃), zirconia (ZrO₂), calcium oxide (CaO), magnesium oxide (MgO), and rare earth oxides.

Various transparent conductive oxides, and equivalent compounds, are known in the art. For example, indium tin oxide is a well known transparent conductive oxide for use in HFEL devices. Other transparent conductive oxides that may be used include, but are not limited to, fluorine tin oxide, zinc oxide doped with gallium or zinc oxide doped with aluminum.

The ground plane may be formed of a conductive material which is chemically compatible with the materials used to construct the electroluminescent device. Aluminum is one presently preferred ground plane material.

The electroluminescent material may be deposited using thin film and thick film techniques. As used herein, thin film techniques are used to deposit a dense layer of electroluminescent material with a thickness typically, but not limited to, less than about 1 μm. Thin film techniques include, but are not limited to, sputtering, metal organic decomposition (MOD) deposition mechanisms, molecular beam epitaxy, evaporation condensation, laser ablation, and others. After the layer is deposited it may be subjected to heat treatment at a temperature ranging from about 300° C. to 1100° C. from about 10 minutes to 1 hour. With thin film devices, the electric field generator is configured to produce a voltage in the range from about 100 volts to 500 volts. The electric field generator is configured to produce an electric field having a frequency greater than about 60 Hz and tuned to a resonance unique to the electroluminescent device. Typical operating frequencies are in the range from about 10,000 Hz to about 20,000 Hz. Higher frequencies on the order of 100,000 Hz, and even 1,000,000 Hz, may be used. The electric field generator may produce a pulsed DC or an AC electric field.

Thick film techniques may be used to deposit a layer of electroluminescent material with a thickness typically, but not limited to, greater than 1 μm. Thick film techniques typically involve obtaining the electroluminescent material in a powdered form, dispersing the material in a binder material, and then forming a layer of the electroluminescent material/binder using techniques such as spin coating, painting, spray coating, tape casting, and various printing techniques. It will be appreciated that the existence of a binder causes the electroluminescent material to be spaced or porous. Hence, thick film techniques do not result in a 100% dense layer of electroluminescent material. With thick film devices, the electric field generator is configured to produce a voltage in the range from about 5000 volts to 20,000 volts. As with thin film devices, the frequency is preferably tuned to a resonant frequency for the device.

Because the brightness and performance of the electroluminescent device depend upon the strength of the electric field that is generated, increasing the capacitance of the device will increase the strength of the electric field that can be generated. A dielectric layer formed of a high dielectric constant material may be disposed between the layer of electroluminescent placed between the electroluminescent material and the transparent conductive oxide because it would tend to block the light generated by the luminescent material. However, dielectric materials that are transparent or optically conductive and chemically compatible with the electroluminescent material may be suitable for use in the present invention. Presently preferred dielectric layer materials include titanate compounds, including but limited to barium titante (BaTiO₃) and strontium barium titanate (SrₓBa₍₁₋ₓ₎TiO₃).

HFEL devices are driven by an electric field rather than current injection such as at a p/n junction. The device construction preferably uses an electrically resistive dielectric material in addition to the luminescent center to increase the electric field while effectively preventing the flow of “resistive current.” The consumption of current is primarily used to overcome quantum excitation of electrons in the luminescent center or dopant ion and coulomb forces within a host lattice structure and dielectric layers. Conductive layers such as transparent conductive oxides and metal films are used as electrode materials.

### DESCRIPTION OF THE SEVERAL VIEWS OF THE DRAWINGS

A more particular description of the invention briefly described above will be rendered by reference to specific embodiments thereof which are illustrated in the appended drawings. These drawings depict only typical embodiments of the invention and are not therefore to be considered to be limiting of its scope. The invention will be described and explained with additional specificity and detail through the use of the accompanying drawings in which:

FIG. 1 is a schematic representation of an electroluminescent device within the scope of the present invention.

FIG. 2 is a schematic representation of an electroluminescent device within the scope of the present invention.

FIG. 3 is a graph illustrating the red spectrum of light emitted by an electroluminescent material comprising as a ceramic oxide host material MgO (1 mole) and GeO₂ (0.9925 mole), with a dopant of MnO₂ (0.0075 mole).

FIG. 4 is a graph illustrating the green spectrum of light emitted by an electroluminescent material comprising as a ceramic oxide host material ZnO (0.2 mole), SrO (0.5 mole), and GeO₂ (0.2925 mole), with a dopant of MnO₂ (0.0075 mole).

FIG. 5 is a graph illustrating the blue spectrum of light emitted by an electroluminescent material comprising as a ceramic oxide host material ZrO₂ (1 mole) and GeO₂ (0.9925 mole), with a dopant of MnO₂ (0.0075 mole).

FIG. 6 is a graph illustrating the “white” spectrum of light emitted by an electroluminescent material comprising as a ceramic oxide host material ZnO (1 mole), SiO₂ (0.995 mole), GeO₂ (0.1312 mole), and Al₂O₃ (0.25 mole), with a dopant of MnO₂ (0.00375 mole).

### DETAILED DESCRIPTION OF THE INVENTION

The present invention provides compounds exhibiting electroluminescent properties when subjected to an electric field and related electroluminescent devices. The electroluminescent materials are based upon a multicomponent ceramic oxide host compound and one or more metal oxide dopant compounds which form a solid solution with the ceramic oxide host compound.

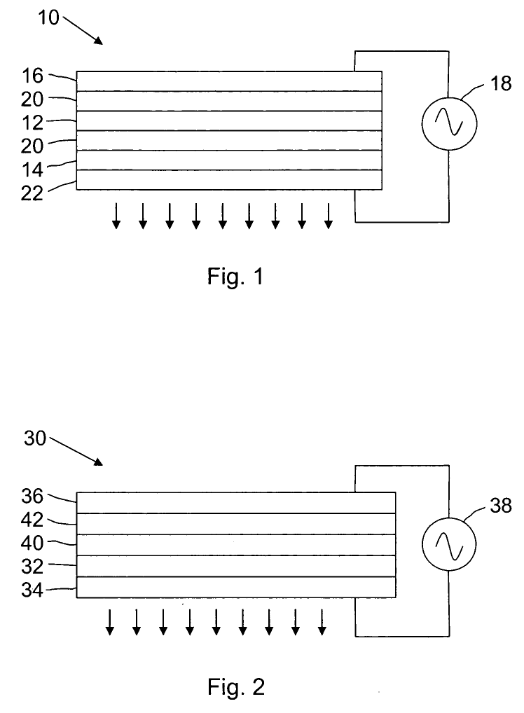

FIG. 1 discloses a schematic representation of an electroluminescent device 10 within the scope of the present invention. Electroluminescent device 10 includes a layer of electroluminescent material 12 disposed between a transparent conductive oxide layer 14 and a ground plane 16. An electric field generator 18 is electrically connected to the conductive oxide 14 layer and the ground plane 16 for generating an electric field. The layer of electroluminescent material 12 is coated with at least one barrier layer 20, and preferably a pair of barrier layers 20, to inhibit chemical reaction of the electroluminescent material 12. The layers are deposited on a substrate 22, in this case a transparent substrate such as glass. The arrows indicate the direction light is emitted by the device. In fabricating the electroluminescent device 10, after each layer is deposited, such as by sputtering or spin coating, the layer is heat treated.

One method of depositing the electroluminescent layer uses the process of metal organic decomposition (MOD). In this process, the metals which form the host ceramic oxide and dopant metal oxide may be in the form of organometallic compounds or soluble salts in a common organic solvent, such as an alcohol. A thin layer is deposited on the substrate, such as by spin coating. The layer is briefly heat treated at a temperature from about 300° C. to 1100° C. for about 10 to 30 seconds to remove the organics. Additional layers are deposited until a sufficient thickness is built up, preferably in the range from about 0.5 to about 2 micron. Thereafter the electroluminescent layer is heat treated at a temperature from about 300° C. to 1100° C. for about 10 to 60 minutes. This heat treating step causes the organic solvent to be completely removed and causes the metals to oxidize into the desired ceramic oxide host crystal.

Because of the heat treating step, chemical reaction between the layers is possible. Therefore, barrier layers 20 are deposited to inhibit reaction of the electroluminescent layer. The barrier layers may have a thickness from about 0.02 to about 1 micron. The barrier layer preferably comprises a low reactive material that is stable at the high temperatures used in heat treating. The barrier layer is preferably a metal oxide, such as, but not limited to, tantalum oxide (Ta₂O₅), alumina (Al₂O₃), zirconia (ZrO₂), calcium oxide (CaO), magnesium oxide (MgO), and rare earth oxides.

Indium tin oxide is one presently preferred transparent conductive oxide layer 14. Other transparent conductive oxides that may be used include, but are not limited to, fluorine tin oxide, zinc oxide doped with gallium or zinc oxide doped with aluminum. The transparent conductive oxide layer may be deposited by sputtering, or similar technique. The ground plane 16 should be chemically stable at high temperatures used in the heat treating step. Aluminum is one presently preferred ground plane 16 material.

FIG. 2 discloses another possible configuration of an electroluminescent device 30 within the scope of the present invention. Electroluminescent device 30 includes a layer of electroluminescent material 32 disposed between a transparent conductive oxide layer 34 and a ground plane 36. An electric field generator 38 is electrically connected to the conductive oxide 34 layer and the ground plane 36 for generating an electric field. The layer of electroluminescent material 32 is coated with at least one barrier layer 40 to inhibit chemical reaction of the electroluminescent material 32. In electroluminescent device 30, the ground plane 36 serves as a substrate upon which the layers are fabricated. The substrate may be silicon, preferably in a (1,1,1) orientation. The arrows indicate the direction light is emitted by the device.

The electroluminescent layer 32 may have a thickness ranging from about 0.5 microns to about 2 microns. The electroluminescent layer may be heat treated at 800° C. to 1100° C. for a period of about one hour. The barrier layer may be tantalum oxide (Ta₂O₅), deposited by sputtering, having a thickness of about 0.5 to 1 micron and heat treated at 800° C. to 1100° C. for a period of about 15 minutes to one hour. It will be appreciated that other materials may be used to form the barrier layer.

A dielectric layer 42 of barium titanate (BaTiO₃) is disposed between the barrier layer 40 and the transparent conductive oxide layer 34. The dielectric layer may be deposited by sputtering and have a thickness between 1 and 2 microns. It may be heat treated at a temperature from about 800° C. to 1100° C. for a period of about 15 minutes to one hour. The use of barrier layers that inhibit chemical reaction during high temperature processing permits one to include a layer of a high dielectric constant material to increase the electric field.

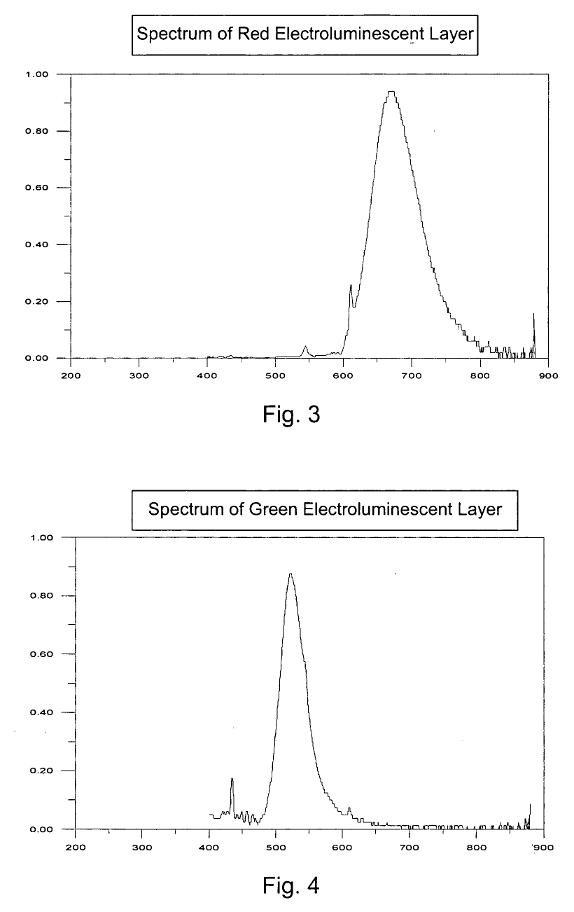

Devices have been made using thick and thin-film technologies, described above. Many colors of the visible, infrared and near UV spectrum have been demonstrated. FIGS. 3, 4, and 5 show the spectrum derived from electroluminescent devices emitting red, green, and blue colors respectively.

The advantage of fabricating devices in thin-film form is to increase brightness of the emitted light. The following equations show that as capacitance increases, the brightness will also increase.

$$Equation 1 \text{:} \qquad C = \frac{{ϵ}_{0} \cdot Area \cdot K}{Thickness}$$

E=½C·V² Equation 2:

Where C is capacitance, ∈₀ is the permittivity of free space, Area is the total area of illumination, K is the dielectric constant, the Thickness is the thickness of the luminescent layer, E is the energy consumed in the device and V is the voltage. Brightness of the device is generally directly related to the energy consumed in the device. Equation 1 shows that decreasing the thickness, increasing the area, and/or increasing the dielectric constant of one or more layers increase the capacitance of the device. From Equation 2, if the capacitance is increased, then the voltage can be decreased to obtain the same electric field energy. It is often desirable to reduce the operating voltage of electroluminescent devices. Therefore, it may be desirable to decrease the thickness of the electroluminescent layer, increase its area, or increase its dielectric constant. Moreover, with all variables constant, a thinner device will generally be brighter than a thicker device. Similarly, a device with a larger area may also be brighter. This suggests thin-film devices may be preferred over thick-film devices, particularly for area illumination.

The ceramic oxide host materials within the scope of the present invention may be prepared as thin or thick films. It should also be noted that the individual solid-state colors that have thus far been generated, red, green, blue, yellow, and a bluish white have their own individual applications in addition to the combinations contemplated for general white light illumination.

### EXAMPLES

The following examples are given to illustrate various embodiments within the scope of the present invention. These are given by way of example only, and it is to be understood that the following examples are not comprehensive or exhaustive of the many embodiments within the scope of the present invention.

### Example 1

An electroluminescent material comprising a ceramic oxide host material of MgO (1 mole)+GeO₂ (0.9925 mole), with a MnO₂ (0.0075 mole) dopant was deposited as a simple thick film with no dielectric layer and was subjected to an electric field of pulsed DC, 2,000 Volts, and 10,000 Hz. FIG. 3 shows a graph from a spectrophotometer showing the predominantly red color emitted by this material. Most of the emitted light covers the region from 600 nm to 800 nm; or covers the whole red region and slightly into the infrared region. Due to the resolution of the spectrometer, it was not possible to determine whether the major peak was due to one electronic transition or was composed of several transitions with several peaks. It is possible the dopant local environment was not confined to a particular defect site but, could be in octahedral or tetrahedral sites with complex spitting of the crystal fields. The dopant can be in several valence states and coordination numbers effectively allowing the dopant to have differing ionic radii.

As can be seen from FIG. 3, the emitted light covers a broad range of wavelengths compared with the light emitted from LEDs, and it is somewhat symmetrical except for the lower intensity—low wavelength side of the spectrum. The assignment of small peaks at about 545 nm and 610 nm has not been made yet.

### Example 2

An electroluminescent material comprising a ceramic oxide host material of ZnO (0.2 mole), SrO (0.5 mole), and GeO₂ (0.2925 mole), with a MnO₂ (0.0075 mole) dopant was deposited as a simple thick film with no dielectric layer and was subjected to an electric field of pulsed DC, 2,000 Volts, and 10,000 Hz. FIG. 4 shows a graph from a spectrophotometer showing the predominantly green color emitted by this material. In FIG. 4, the main emission line is shifted to lower wavelengths and is still quite broad and somewhat symmetrical. There seems to be another peak, at about 550 nm, or shoulder attached to the main peak. The smaller peaks at 430 nm and 615 nm are not assigned to any electron transition

### Example 3

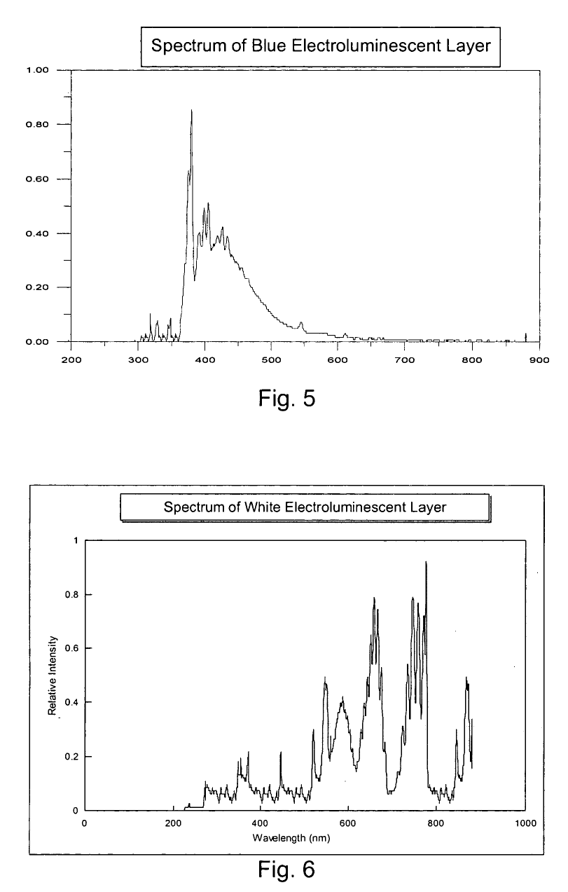

An electroluminescent material comprising a ceramic oxide host material of ZrO₂ (1 mole) and GeO₂ (0.9925 mole), with a MnO₂ (0.0075 mole) dopant was deposited as a simple thick film with no dielectric layer and was subjected to an electric field of pulsed DC, 2,000 Volts, and 10,000 Hz. FIG. 5 shows a graph from a spectrophotometer showing the predominantly blue color emitted by this material. FIG. 5 shows an even broader spectrum than the red or the green, but there are also more peaks indicating more detailed or complicated electron transitions for this particular material. What is interesting is that a significant amount, and the largest peak, of the emitted light is in the UV region, centered at about 385 nm and extending down to about 360 nm.

### Example 4

An electroluminescent material comprising a ceramic oxide host material of ZnO (1 mole), SiO₂ (0.995 mole), GeO₂ (0.1312 mole), and Al₂O₃ (0.25 mole), with a dopant of MnO₂ (0.00375 mole) was prepared as a simple thick film with no dielectric layer and subjected to an electric field of pulsed DC, 2,000 Volts, 10,000 Hz. FIG. 6 shows a graph from a spectrophotometer showing the “white” color emitted by this material. Without being bound by theory, it is presently believed that the addition of alumina to the host material contributed to the white light produced. In FIGS. 3-6 the “Y” axis is in relative arbitrary units.

It is significant that the same dopant ion is used as a luminescent center responsible for the red, green, blue, and white colors in Examples 1-4. Only the host material was changed. The three different RGB phosphors of Examples 1-3 have been mixed to give a white light output.

### Example 5

electroluminescent material comprising a ceramic oxide host material of CaO (1 mole) and GeO₂ (0.9925 mole), with a MnO₂ (0.0075 mole) dopant was deposited as a simple thick file with no dielectric layer and subjected to an electric field. The resulting spectrum shows a good yellow colored emission.

A variety of different electroluminescent materials have been prepared which emit a broad range of colors. The materials were categorized based upon the emission color as blue, green, red, yellow, pink, and white phosphors:

TABLE 2
Blue Phosphors

| Sample | Host | Dopant |
|---|---|---|
| 1 | ZrO₂ (1 mole) | MnO₂ (0.005-0.05 mole) |
| | GeO₂ (0.995-0.95 mole) | |
| 2 | ZrO₂ (1 mole) | MnO₂ (0.005-0.05 mole) |
| | Ga₂O₃ (0.995-0.95 mole) | |
| 3 | ZrO₂ (1 mole) | SnO₂ (0.005-0.05 mole) |
| | GeO₂ (0.995-0.95 mole) | |
| 4 | ZnO (1 mole) | HfO₂ (0.005-0.05 mole) |
| | GeO₂ (0.995-0.95 mole) | |
| 5 | ZrO₂ (1 mole) | MnO₂ (0.005 mole) |
| | Ga₂O₃ (0.4975 mole) | |

TABLE 3
Green Phosphors

| Sample | Host | Dopant |
|---|---|---|
| 1 | ZnO (0.2-0.5 mole) | MnO₂ (0.005-0.05 mole) |
| | SrO (0.2-0.5 mole) | |
| | GeO₂ (0.1-0.3 mole) | |
| 2 | ZnO (1 mole) | Al₂O₃ (0.0025 mole) |
| | SiO₂ (0.995 mole) | As₂O₃ (0.0025 mole) |
| | | MnO₂ (0.005 mole) |

TABLE 4
Red Phosphors

| Sample | Host | Dopant |
|---|---|---|
| 1 | MgO (1 mole) | MnO₂ (0.005-0.05 mole) |
| | GeO₂ (0.995-0.95 mole) | |
| 2 | La₂O₃ (0.1 mole) | Eu₂O₃ (0.0025-0.05) |
| | SrO (0.498-0.45 mole) | |
| | Ga₂O₃ (0.4 mole) | |
| 3 | La₂O₃ (0.4 mole) | Eu₂O₃ (0.0025 mole) |
| | SrO (0.2 mole) | |
| | Ga₂O₃ (0.4 mole) | |

TABLE 5
Yellow Phosphor

| Sample | Host | Dopant |
|---|---|---|
| 1 | CaO (1 mole) | MnO₂ (0.005-0.05) |
| | GeO₂ (0.995-0.95) mole | |

TABLE 6
Pink Phosphor

| Sample | Host | Dopant |
|---|---|---|
| 1 | Y₂O₃ (0.3 mole) | Dy₂O₃ (0.0038 mole) |
| | GeO₂ (0.995 mole) | |

TABLE 7
White Phosphors

| Sample | Host | Dopant |
|---|---|---|
| 1 | ZnO (1 mole) | Dy₂O₃ (0.0025 mole) |
| | SiO₂ (0.295 mole) | |
| | Y₂O₃ (0.1 mole) | |
| 2 | ZnO (1 mole) | MnO₂ (0.00375 mole) |
| | SiO₂ (0.995 mole) | |
| | GeO₂ (0.1312 mole) | |
| | Al₂O₃ (0.25 mole) | |

It will be appreciated that the present invention provides electroluminescent materials and devices that produce non-thermal light in response to an electric field. The electroluminescent materials are based upon a multicomponent ceramic oxide host compound and one or more metal oxide dopant compounds which form a solid solution with the ceramic oxide host compound. Because the compositions are based upon metal oxides, high temperature stability and rugged solid state devices may be fabricated. Thin and thick film processing techniques may be used to fabricate devices that produce light at a broad range of wavelengths. The use of barrier layers inhibit chemical reaction with the electroluminescent material during the high temperature processing steps.

The present invention may be embodied in other specific forms without departing from its structures, methods, or other essential characteristics as broadly described herein and claimed hereinafter. The described embodiments are to be considered in all respects only as illustrative, and not restrictive. The scope of the invention is, therefore, indicated by the appended claims, rather than by the foregoing description. All changes that come within the meaning and range of equivalency of the claims are to be embraced within their scope.

1. An electroluminescent device comprising:
a layer of electroluminescent material comprising:
a ceramic oxide host compound; and
one or more metal oxide dopant compounds which form a solid solution with the ceramic oxide host compound;
at least one barrier layer contacting the layer of electroluminescent material to inhibit chemical reaction of the electroluminescent material, wherein the barrier layer comprises a low reactive material that is stable at high temperature;
a transparent conductive oxide layer;
a ground plane, wherein the transparent conductive oxide and the ground plane are disposed on opposite sides of the electroluminescent material; and
an electric field generator electrically connected to the conductive oxide layer and the ground plane for generating an electric field.

2. The electroluminescent device according to claim 1, further comprising a dielectric layer disposed between the layer of electroluminescent material and the ground plane.

3. The electroluminescent device according to claim 2, wherein the dielectric layer comprises a titanate compound.

4. The electroluminescent device according to claim 3, wherein the titanate compound is barium titanate (BaTiO₃).

5. The electroluminescent device according to claim 3, wherein the titanate compound is strontium barium titanate (SrₓBa₍₁₋ₓ₎TiO₃).

6. The electroluminescent device according to claim 1, wherein the ceramic oxide host compound comprises two or more metal oxide compounds and wherein at least one of the metal oxide compounds is ZrO₂, Ga₂O₃, GeO₂, SiO₂, SnO₂, or PbO₂.

7. The electroluminescent device according to claim 6, wherein the ceramic oxide host compound comprises GeO₂ and one or more oxides selected from ZrO₂, SiO₂, Al₂O₃, Y₂O₃, ZnO, MgO, CaO, and SrO.

8. The electroluminescent device according to claim 6, wherein the ceramic oxide host compound comprises ZrO₂ and one or more oxides selected from GeO₂, and Ga₂O₃, and SrO.

9. The electroluminescent device according to claim 6, wherein the ceramic oxide host compound comprises SiO₂ and one or more oxides selected from ZnO and Y₂O₃.

10. The electroluminescent device according to claim 7, wherein the ceramic oxide host compound comprises GeO₂ and ZnO, and wherein the metal oxide dopant is HfO₂.

11. The electroluminescent device according to claim 7, wherein the ceramic oxide host compound comprises GeO₂, SrO, and ZnO, and wherein the metal oxide dopant is MnO₂.

12. The electroluminescent device according to claim 7, wherein the ceramic oxide host compound comprises GeO₂ and MgO, and wherein the metal oxide dopant is MnO₂.

13. The electroluminescent device according to claim 7, wherein the ceramic oxide host compound comprises GeO₂ and CaO, and wherein the metal oxide dopant is MnO₂.

14. The electroluminescent device according to claim 7, wherein the ceramic oxide host compound comprises GeO₂ and Y₂O₃, and wherein the metal oxide dopant is Dy₂O₃.

15. The electroluminescent device according to claim 8, wherein the ceramic oxide host compound comprises ZrO₂ and GeO₂, and wherein the metal oxide dopant is MnO₂.

16. The electroluminescent device according to claim 8, wherein the ceramic oxide host compound comprises ZrO₂ and Ga₂O₃, and wherein the metal oxide dopant is MnO₂.

17. The electroluminescent device according to claim 8, wherein the ceramic oxide host compound comprises ZrO₂ and GeO₂, and wherein the metal oxide dopant is SnO₂.

18. The electroluminescent device according to claim 9, wherein the ceramic oxide host compound comprises SiO₂ and ZnO, and wherein the metal oxide dopant comprises MnO₂, Al₂O₃, and As₂O₃.

19. The electroluminescent device according to claim 9, wherein the ceramic oxide host compound comprises SiO₂, ZnO, and Y₂O₃, and wherein the metal oxide dopant is Dy₂O₃.

20. The electroluminescent device according to claim 9, wherein the ceramic oxide host compound comprises SiO₂, ZnO, GeO₂, and Al₂O₃ and wherein the metal oxide dopant is MnO₂.

21. The electroluminescent device according to claim 1, wherein the ceramic oxide host compound comprises La₂O₃, SrO, and Ga₂O₃, and the metal oxide dopant compound comprises Eu₂O₃.

22. The electroluminescent device according to claim 1, wherein the ceramic oxide host compound comprises multiple metal oxides to provide a crystal structure that is compatible with the one or more dopant compounds.

23. The electroluminescent device according to claim 1, wherein the ceramic oxide host compound is a solid solution of multiple metal oxide with a band gap ranging from about 1 eV to 4 eV.

24. The electroluminescent device according to claim 1, wherein the metal oxide dopant compound is selected from MnO₂, SnO₂, HfO₂, Al₂O₃, Dy₂O₃, As₂O₃, Eu₂O₃, and mixtures thereof.

25. The electroluminescent device according to claim 1, wherein the dopant is present in the host at an amount in the range from about 0.002 mole % to 0.1 mole %.

26. The electroluminescent device according to claim 1, wherein the metal oxide dopant compounds are selected to provide acceptor and donor sites within the ceramic oxide host compound.

27. The electroluminescent device according to claim 1, wherein the barrier layer comprises a metal oxide.

28. The electroluminescent device according to claim 1, wherein the barrier layer comprises tantalum oxide (Ta₂O₅).

29. The electroluminescent device according to claim 1, wherein the barrier layer comprises alumina.

30. The electroluminescent device according to claim 1, wherein the barrier layer comprises zirconia.

31. The electroluminescent device according to claim 1, wherein the barrier layer is calcium oxide, magnesium oxide, or a rare earth oxide.

32. The electroluminescent device according to claim 1, wherein the layer of electroluminescent material is deposited as a dense thin film.

33. The electroluminescent device according to claim 1, wherein the layer of electroluminescent material is deposited as a dense thin film having a thickness less than about 1 micron.

34. The electroluminescent device according to claim 32, wherein the electric field generator is configured to produce a voltage in the range from about 100 volts to 500 volts.

35. The electroluminescent device according to claim 1, wherein the layer of electroluminescent material is deposited as a thick film.

36. The electroluminescent device according to claim 1, wherein the layer of electroluminescent material is deposited as a thick film having a thickness greater than about 1 micron.

37. The electroluminescent device according to claim 35, wherein the electric field generator is configured to produce a voltage in the range from about 5,000 volts to 20,000 volts.

38. The electroluminescent device according to claim 1, wherein the electric field generator is configured to produce an electric field having a frequency greater than about 60 Hz and tuned to a resonance unique to the electroluminescent device.

39. The electroluminescent device according to claim 1, wherein the transparent conductive oxide is indium tin oxide.

40. The electroluminescent device according to claim 1, wherein the transparent conductive oxide is zinc oxide doped with gallium or zinc oxide doped with aluminum.

41. The electroluminescent device according to claim 1, further comprising a dielectric layer disposed between the layer of electroluminescent material and the ground plane, wherein the ceramic oxide host compound comprises two or more metal oxide compounds and wherein at least one of the metal oxide compounds is a first metal oxide compound selected from Ga₂O₃, ZrO₂, GeO₂, SnO₂, and PbO₂ and at least one other metal oxide compound different from the first metal oxide compound is selected from ZrO₂, GeO₂, SnO₂, Al₂O₃, Y₂O₃, ZnO, MgO, CaO, SrO, and La₂O₃, wherein the metal oxide dopant compound is selected from MnO₂, SnO₂, HfO₂, Al₂O₃, Dy₂O₃, As₂O₃, Eu₂O₃, and mixtures thereof, and the barrier layer is a metal oxide.

42. The electroluminescent device according to claim 41, wherein the dielectric layer comprises a titanate compound.

43. The electroluminescent device according to claim 41, wherein the barrier layer is tantalum oxide, alumina, zirconia, calcium oxide, magnesium oxide, or a rare earth oxide.

44. An electroluminescent compound which emits non-thermal light in response to an electric field comprising:
a multicomponent ceramic oxide host compound comprising two or more metal oxide compounds, wherein a first metal oxide compound is selected from ZrO₂, Ga₂O₃, GeO₂, SnO₂, and PbO₂, and a second metal oxide compound different from the first metal oxide compound is selected from ZrO₂, GeO₂, SnO₂, Al₂O₃, Y₂O₃, ZnO, MgO, CaO, Ga₂O₃, SrO, and La₂O₃; and
one or more dopant compounds which form a one phase solid solution with the ceramic oxide host compound, wherein the one or more dopant compounds are selected to be different than the ceramic oxide host and are metal oxides selected from MnO₂, SnO₂, HfO₂, Al₂O₃, Dy₂O₃, As₂O₃, and Eu₂O₃, and mixtures thereof.

45. The electroluminescent compound according to claim 44, wherein the ceramic oxide host compound comprises GeO₂ and one or more oxides selected from ZrO₂, Al₂O₃, Y₂O₃, ZnO, MgO, CaO, and SrO.

46. The electroluminescent compound according to claim 44, wherein the ceramic oxide host compound comprises ZrO₂ and one or more oxides selected from GeO₂, and Ga₂O₃, and SrO.

47. The electroluminescent compound according to claim 44, wherein the ceramic oxide host compound comprises SiO2 and one or more oxides selected from ZnO and Y₂O₃.

48. The electroluminescent compound according to claim 44, wherein the ceramic oxide host compound comprises Ga₂O₃ and one or more oxides selected from ZrO₂, SrO, and La₂O₃.
